(19) United States
(12) Patent Application Publication
(10) Pub. No.: US 2008/0093315 A1
(43) Pub. Date: Apr. 24, 2008

(54) Support for Semiconductor Substrate

(75) Inventor: Akira Okabe, Nagasaki (JP)

Correspondence Address: JORDAN AND HAMBURG LLP, 122 EAST 42ND STREET, SUITE 4000, NEW YORK, NY, 10168, US

(73) Assignee: EPICREW CORPORATION, OHMURA-SHI NAGASAKI, JAPAN (JP)

(21) Appl. No.: 11/666,371

(22) PCT Filed: Oct. 29, 2004
(86) PCT No.: PCT/JP04/16157

§ 371 Date: May 16, 2007

(51) Int. Cl. H01L 21/02

(52) U.S. Cl. 211/41.18

(57) ABSTRACT

It is an object of the present invention to provide a support for a semiconductor substrate capable of correctly measuring a temperature in the vicinity of a semiconductor substrate. A first support plate 2 and second support plate 3 of a wafer support 1, which are made of a material having almost the same thermal conductivity, are integrally superposed. A through-hole formed in the central region of the first support plate 2 is covered with a cap 7. A silicon semiconductor wafer 9 is placed on a wafer support part 4 of the wafer support 1. A space is formed between the silicon semiconductor wafer 9 and a counterbore part 4a. In a groove 5 formed on the second support plate 3, a thermocouple 6 is arranged parallel with a placed surface of the silicon semiconductor wafer 9 in the central region and peripheral region of the support plate to measure the temperature of the silicon semiconductor wafer.

### TECHNICAL FIELD

The present invention relates to a support for a semiconductor substrate. In particular, the present invention relates to a support for a semiconductor substrate which has a temperature measurement means arranged in a central region and peripheral region of a surface of a support plate positioned at a second stage and afterward to correctly measure a temperature in the vicinity of the semiconductor substrate while the semiconductor substrate is processed.

### BACKGROUND OF THE INVENTION

Substrates which have a perfect crystal surface part having no minute defect obtained by depositing and growing an epitaxial layer on a semiconductor substrate have often been used in MPUs or memory ICs in recent years. Examples of methods for depositing and growing a silicon epitaxial layer include a CVD (chemical vapor deposition) method for supplying reaction gas containing material gas such as SiCl₄ and reference gas such as hydrogen onto a silicon substrate heated to a high temperature, and depositing and growing a silicon single crystal on the silicon substrate.

Various apparatuses for depositing and growing the epitaxial layer have existed. FIG. 1 shows a schematic sectional view of one example of a conventional semiconductor manufacturing apparatus for depositing and growing the epitaxial layer.

The semiconductor manufacturing apparatus shown herein is composed of a reaction chamber 101, halogen lamps 106 arranged around the reaction chamber 101 and a wafer support 102 which supports a semiconductor wafer in the reaction chamber 101. The reaction chamber 101 is composed of a first clamp 109 made of stainless steel in which a reaction gas inlet 104 is formed, a second clamp 110 made of stainless steel in which a reaction gas outlet 105 is formed, and a quartz glass plate 107 fixed by clamping both ends of the quartz glass plate 107 by the first clamp and the second clamp.

When the epitaxial layer is deposited and grown using the semiconductor manufacturing apparatus constituted as described above, a semiconductor wafer 103 is heated by placing the semiconductor wafer 103 on the wafer support, introducing reaction gas 108 from the reaction gas inlet 104, exhausting the reaction gas 108 from the reaction gas outlet 105 to flow the reaction gas into the reaction chamber 101, and irradiating the halogen lamps 106. The epitaxial layer is deposited and grown by the reaction gas and the heat.

Meanwhile, although the semiconductor substrate is heated to a predetermined temperature, and the epitaxial layer is deposited and grown while the temperature of the semiconductor substrate is maintained within a predetermined temperature range, it is necessary to correctly grasp whether the temperature of the semiconductor substrate is within the predetermined temperature range in order to stably deposit and grow the epitaxial layer.

Therefore, U.S. Pat. No. 6,053,982 discloses that a thermocouple, which upwardly extends through a shaft and terminates at a central lower part of a support, correctly measures a temperature in the vicinity of a central part of a semiconductor substrate. FIG. 2 is a schematic sectional view of a conventional support having a thermocouple upwardly extending through a shaft.

A wafer support 111 shown in FIG. 2 is provided with an upper part 112 and a lower part 113. A semiconductor wafer 118 is placed on a space keeping member (spacer) 117 projected in a recess of the wafer support. Grooves 115, 116 where gas flows are formed on the lower part 113. A thermocouple 114, which extends to the central region of the upper part 112 from the lower part of the support through a shaft 119, measures a temperature in the vicinity of the center of the semiconductor wafer 118.

### DISCLOSURE OF THE INVENTION

### Problems to be Solved by the Invention

However, since the temperature is measured at only one position in only the central region of the support, and the temperature distribution in the surface of the support is nonuniform in the temperature measurement using the thermocouple extending to a portion in the vicinity of the center of the support through the shaft in the conventional support, the temperature in the vicinity of the semiconductor wafer is not sufficiently and correctly measured. Also, since the thermocouple is not arranged in the vicinity of the semiconductor wafer in the case of a support for placing a plurality of semiconductor wafers in a peripheral region as in a plural-wafer type support, the temperature in the vicinity of the semiconductor wafer is not sufficiently and correctly measured.

The present invention has been accomplished in view of the foregoing and other problems. It is an object of the present invention to provide a support for a semiconductor substrate capable of correctly measuring a temperature in the vicinity of the semiconductor substrate.

### Means for Solving the Problems

In order to attain the above object, a support for a semiconductor substrate of the present invention is composed of a plurality of accumulated support plates and supports the semiconductor substrate in a reaction chamber, wherein the semiconductor substrate is placed on the surface of the support plate positioned at the uppermost stage; and a temperature measurement means is arranged in a central region and peripheral region of a surface of the support plate positioned at a second stage and afterward.

Herein, the disturbance in the measurement due to reaction products, etc., formed on the temperature measurement means can be reduced by arranging the temperature measurement means on the support plate positioned at the second stage and afterward. That is, when the temperature measurement means is arranged on the surface of the support plate positioned at the uppermost stage, the reaction products, etc., in the reaction chamber are adhered to the temperature measurement means. However, when the temperature measurement means is arranged on the support plate positioned at the second stage and afterward, the adhesion of the reaction products, etc., in the reaction chamber to the temperature measurement means can be reduced. Also, not only the temperature of the central region of the surface of the support plate but also that of the peripheral region can be measured by arranging the temperature measurement means in the central region and peripheral region of the surface of the support plate positioned at the second stage and afterward, and thereby the temperatures of a plurality of positions of the support plate can be measured.

### EFFECTS OF THE INVENTION

The support for the semiconductor substrate according to the present invention can correctly measure the temperature in the vicinity of the semiconductor substrate.

### BRIEF DESCRIPTION OF THE DRAWINGS

FIG. 1 is a schematic sectional view of an example of a conventional semiconductor manufacturing apparatus for depositing and growing an epitaxial layer.

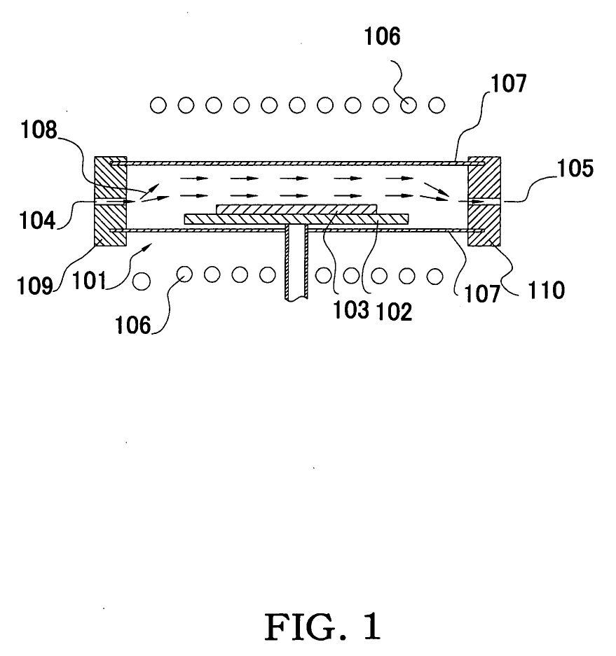

FIG. 2 is a schematic sectional view of a conventional support having a thermocouple upwardly extending through a shaft.

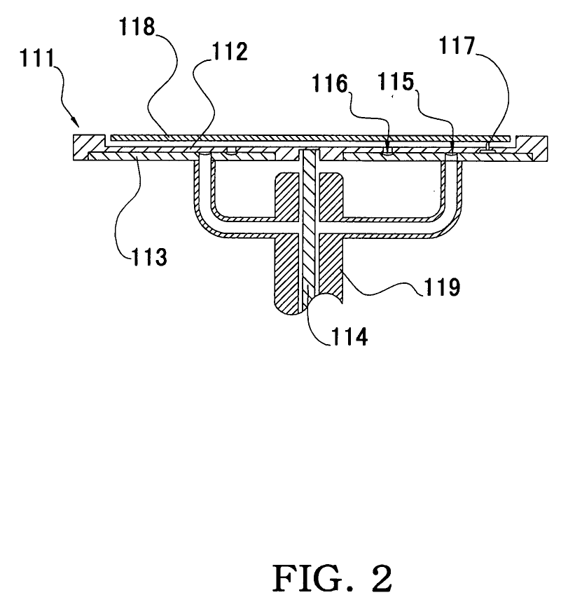

FIG. 3 is a schematic exploded perspective view showing an example of a plural-wafer type support for a semiconductor substrate to which the present invention is applied.

FIG. 4 is a schematic sectional view showing an example of a semiconductor manufacturing apparatus in which a semiconductor wafer is placed on a wafer support shown in FIG. 3. The section of the wafer support is obtained by cutting the wafer support along line I-I of FIG. 3.

### DESCRIPTION OF SYMBOLS

1: Wafer support
2: First support plate
3: Second support plate
4: Wafer support part
4a: Counterbore part
5: Groove
6: Thermocouple
7: Cap
8: Support rotating member
9: Silicon semiconductor wafer
10: Reaction chamber
11: Reaction gas inlet
12: Reaction gas outlet
13: Halogen lamp
14: Quartz glass plate
15: Reaction gas containing SiCl₄ gas and hydrogen gas
16: First clamp
17: Second clamp

### BEST MODE FOR CARRYING OUT THE INVENTION

Hereinafter, an embodiment of the present invention will be described with reference to the drawings, and the embodiment will be provided for understanding the present invention.

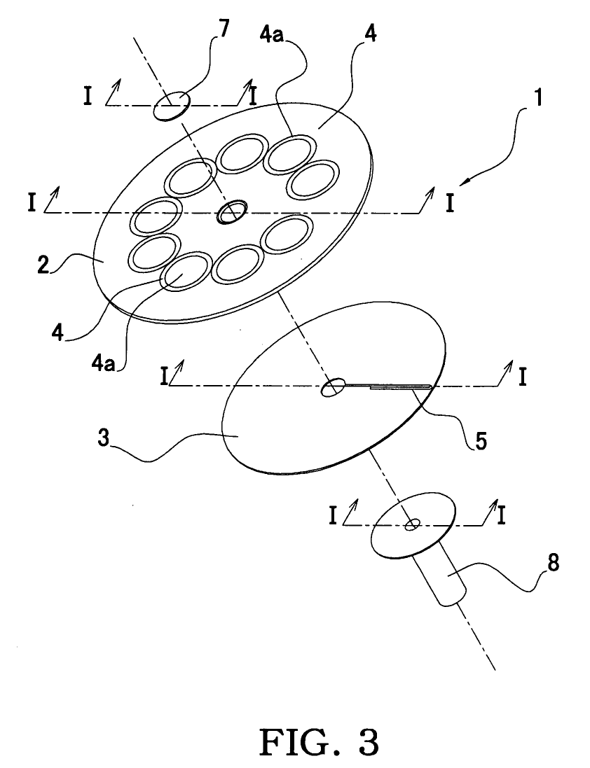

FIG. 3 is a schematic exploded perspective view showing an example of a plural-wafer type support for a semiconductor substrate to which the present invention is applied. A circular wafer support 1 is composed of a first disk-shaped support plate 2, a second disk-shaped support plate 3, a support rotating member 8 and a cap 7. The first disk-shaped support plate 2 is composed of a wafer support part 4 which is depressed in a circle shape in two stages and supports a semiconductor wafer in the upper stand and a counterbore part 4a in the lower stand. The first disk-shaped support plate 2 has a through-hole formed at a center thereof. Positions for placing the semiconductor wafer are annularly arranged. The second disk-shaped support plate 3 has a groove 5 formed at one position in the radial direction so that a temperature measurement means such as a thermocouple and an optical fiber is arranged in the central region and peripheral region of the support plate. The second disk-shaped support plate 3 has a through-hole formed in the center thereof. The support rotating member 8 is connected to a driving apparatus (not shown) and enables the rotation of the wafer support 1. The cap 7 covers the through-hole formed at the center of the first support plate.

Herein, as long as the semiconductor wafer can be supported, the position where the semiconductor wafer is placed may be depressed in three stages. The displacement of the semiconductor wafer due to reaction gas flow can be prevented by placing the semiconductor wafer in the recess.

Herein, as long as the temperature measurement means such as a thermocouple and an optical fiber can be arranged in the central region and peripheral region of the surface of the support plate positioned at the second stage and afterward, the groove may not be necessarily formed. Also, as long as the temperature measurement means such as the thermocouple and the optical fiber can be arranged in the central region and peripheral region of the surface of the support plate at the second stage and afterward, a plurality of grooves may be formed. Furthermore, as long as the temperature measurement means such as the thermocouple and the optical fiber can be arranged in the central region and peripheral region of the surface of the support plate positioned at the second stage and afterward, the groove may not be necessarily formed in the radial direction. For example, the groove may be formed in a spiral manner. Also, as long as the temperature measurement means such as the thermocouple and the optical fiber can be arranged in the central region and peripheral region of the surface of the support plate positioned at the second stage and afterward, the groove may be necessarily formed in neither the central region nor the peripheral region, and may be formed in either the central region or the peripheral region.

As long as the temperature measurement means such as the thermocouple and the optical fiber can be arranged in the central region and peripheral region of the surface of the support plate positioned at the second stage and afterward, a tube made of quartz may be arranged in the groove formed on the support plate at the second stage and afterward, and the temperature measurement means such as the thermocouple and the optical fiber may be arranged in the tube. Thereby, the temperature measurement means can be protected from the reaction gas. Furthermore, at least one kind of gas selected from inactive gases, for example, nitrogen, helium, neon, argon, krypton, xenon and radon may be flown in the tube in which the temperature measurement means is arranged and which is made of quartz to always maintain the temperature measurement means clean.

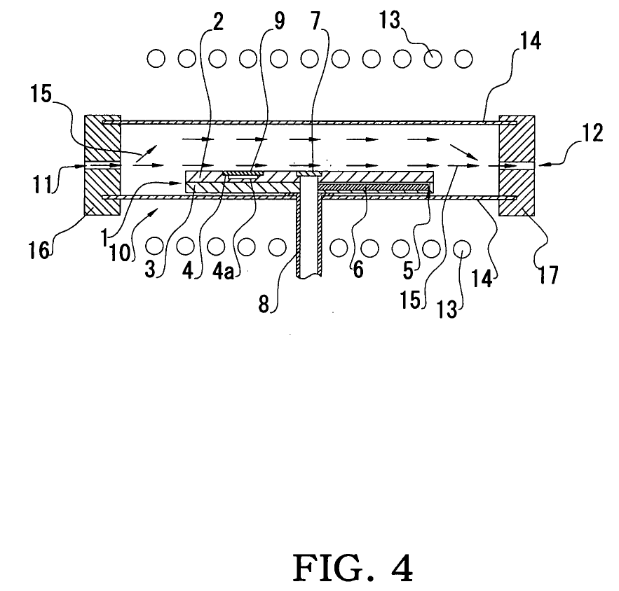

FIG. 4 is a schematic sectional view showing an example of the semiconductor manufacturing apparatus having the semiconductor wafer on the wafer support shown in FIG. 3. The cross section of the wafer support is obtained by cutting the wafer support along line I-I of FIG. 3.

The semiconductor manufacturing apparatus shown in FIG. 4 is composed of a reaction chamber 10, halogen lamps 13 arranged around the reaction chamber, and a disk-shaped wafer support 1 for supporting a silicon semiconductor wafer 9 in the reaction chamber. The reaction chamber 10 is composed of a first clamp 16 made of stainless steel which has a reaction gas inlet 11, a second clamp 17 made of stainless steel which has a reaction gas outlet 12, and a quartz glass plate 14 having both ends tightened and fixed by the first clamp and second clamp. Herein, as long as the first clamp 16 and the second clamp 17 can tighten and fix the quartz glass plate 14, the clamps may be made of quartz.

The first support plate 2 and second support plate 3 of the wafer support 1, which include a material having almost the same thermal conductivity, are integrally superposed. A through-hole formed in the central region of the first support plate 2 is covered with a cap 7. Since the first support plate 2 and the second support plate 3 include the material having almost the same thermal conductivity, even when a thermocouple 6 is not arranged on the same surface as the silicon semiconductor wafer 9, the temperature in the vicinity of the silicon semiconductor wafer can be measured with equal accuracy to the case where the thermocouple 6 is arranged on the same surface as the silicon semiconductor wafer 9.

The silicon semiconductor wafer 9 is placed on the wafer support part 4 of the wafer support 1. A space is formed between the silicon semiconductor wafer 9 and a counterbore part 4a. In the groove 5 formed on the second support plate 3, the thermocouple 6 is arranged parallel with the placed surface of the silicon semiconductor wafer 9 in the central region and peripheral region of the support plate to measure the temperature in the vicinity of the silicon semiconductor wafer. The temperatures in a plurality of positions of the support plate can be measured by arranging the thermocouple in the central region and peripheral region of the support plate, thereby exact temperature measurement is made possible. Also, the support rotating member 8 is connected to a driving apparatus (not shown), thereby the rotation of the wafer support 1 is made possible.

Herein, although the first support plate 2 and the second support plate 3 is composed of the material having almost the same thermal conductivity, as long as the thermocouple can be arranged in the central region and peripheral region of the surface of the support plate positioned at the second stage and afterward, the first support plate 2 and the second support plate 3 may not be composed of the material having almost the same thermal conductivity. Also, as long as the first support plate 2 and the second support plate 3 are composed of the same material (SiC), the temperature in the vicinity of the silicon semiconductor wafer can be more accurately measured.

When epitaxial deposit growth is conducted using the above semiconductor manufacturing apparatus, the silicon semiconductor wafer 9 is placed on the first support plate 2 of the disk-shaped wafer support 1 in the reaction chamber 10, and reaction gas 15 which contains silicon tetrachloride (SiCl₄) gas and hydrogen gas from the reaction gas inlet 11 is introduced into the reaction chamber 10. The reaction gas 15 containing the SiCl₄ gas and the hydrogen gas flows in the vicinity of the silicon semiconductor wafer 9. The inside of the reaction chamber is irradiated with light from the halogen lamps 13 arranged around the reaction chamber, while the silicon semiconductor wafer 9 is heated. The epitaxial deposit growth is then conducted by the heat and the reaction gas.

In the deposit growth process, the thermocouple 6 arranged in the central region and peripheral region of the second support plate 3 of the wafer support 1 measures the temperature in the vicinity of the semiconductor wafer to investigate whether the silicon semiconductor wafer 9 is heated to a predetermined temperature (1000 to 1200° C.). When the temperature of the silicon semiconductor wafer 9 does not reach the predetermined temperature, the temperature is controlled so that the temperature suitably reaches the predetermined temperature by increasing the heat quantity of the halogen lamps 13, etc. In the deposit growth process, the temperature is always measured by the thermocouple 6.

Herein, since the epitaxial layer is hardly formed on the thermocouple as compared with the case where the thermocouple is arranged on the first support plate 2 by arranging the thermocouple 6 on the second support plate 3, and the temperature measurement is hardly disturbed, the temperature can be stably measured. Also, since the thermocouple is arranged in the central region and peripheral region of the second support plate 3, the temperatures of the plurality of positions of the support plate can be measured. As a result, the temperature in the vicinity of the semiconductor wafer having a large area can be strictly measured in the single-wafer type support. Also, in the plural-wafer type support, the temperature measurement accuracy in the vicinity of the semiconductor wafer is enhanced. In both the single-wafer type support and the plural-wafer type support, the temperature in the vicinity of the semiconductor wafer can be correctly measured.

Herein, although the halogen lamps are used as a light source, as long as the light source can heat the silicon semiconductor wafer 9, an optional light source may be used, and for example, an infrared lamp may be used.

Also, although an example of a semiconductor manufacturing apparatus which has a box-shaped reaction chamber is shown in FIG. 4, as long as the semiconductor manufacturing apparatus to which the present invention is applied can accommodate the above wafer support and heat the semiconductor wafer, the semiconductor manufacturing apparatus may have any shape. For example, the semiconductor manufacturing apparatus may have a hemispherical dome type reaction chamber and a reaction chamber having a bell shape.

The example using the silicon substrate is mentioned in the present embodiment. However, any substrate may be used as long as the epitaxial growth can be conducted on the substrate. For example, a gallium arsenide (GaAs) substrate and a zinc telluride (ZnTe) substrate may be used. As long as an epitaxial layer can be deposited and grown on the substrate, any material gas may be used. For example, when the gallium arsenide substrate is used, gas which contains Ga is used, and gas containing Te is used when the zinc telluride substrate is used.

Next, an epitaxial growth step will be described.

While the wafer support 1 holding the silicon semiconductor wafer 9 is rotated by a driving apparatus (not shown), the silicon semiconductor wafer 9 is heated to 1000 to 1200° C. by the halogen lamps 13.

Next, the epitaxial growth is conducted by introducing the reaction gas 15 containing the SiCl₄ gas and the hydrogen gas into the reaction chamber 10 from the reaction gas inlet 11.

The SiCl₄ gas is introduced into the reaction chamber 10 as the material gas contained in the reaction gas. However, as long as the material gas is gas containing silicon atoms, any material gas may be used. For example, trichlorosilane (SiHCl₃) gas, dichlorosilane (SiH₂Cl₂) gas or silane (SiH₄) gas may be introduced into the reaction chamber 10.

Thus, the epitaxial layer is hardly formed on the thermocouple by arranging the thermocouple on the second support plate as compared with the case where the thermocouple is arranged on the first support plate, and the temperature measurement is hardly disturbed. Thereby, the temperature can be stably measured. Also, since the thermocouple is arranged in the central region and peripheral region of the second support plate, the temperatures of the plurality of positions of the support plate can be measured, and the temperature in the vicinity of the semiconductor wafer can be correctly measured even in both the single-wafer type support and the plural-wafer type support.

1. A support for a semiconductor substrate which is composed of a plurality of accumulated support plates and supports the semiconductor substrate in a reaction chamber, wherein the semiconductor substrate is placed on the surface of the support plate positioned at the uppermost stage; and a temperature measurement means is arranged in a central region and peripheral region of a surface of the support plate positioned in a second stage and afterward.

2. The support for a semiconductor substrate according to claim 1, wherein a groove is formed on the surface of the support plate positioned at the second stage and afterward; and the temperature measurement means is arranged in the groove.

3. The support for a semiconductor substrate according to claim 1 or 2, wherein the plurality of support plates have almost the same thermal conductivity.

4. The support for a semiconductor substrate according to claim 1 or 2, wherein the plurality of support plates are made of the same material.

5. The support for a semiconductor substrate according to claim 1 or 2, wherein the temperature measurement means is a thermocouple.
